(19) United States
(12) Patent Application Publication
(10) Pub. No.: US 2014/0292415 A1
(43) Pub. Date: Oct. 2, 2014

(54) SEMICONDUCTOR DEVICE HEAT DISSIPATION USING HIGH THERMAL CONDUCTIVITY DIELECTRIC LAYER

(71) Applicant: SKYWORKS SOLUTIONS, INC., Woburn, MA (US)

(72) Inventor: Stephen Joseph KOVACIC, Ottawa (CA)

(21) Appl. No.: 14/222,979

(22) Filed: Mar. 24, 2014

Related U.S. Application Data
(60) Provisional application No. 61/805,405, filed on Mar. 26, 2013.

(51) Int. Cl. H01L 23/373; H01L 29/66; H03F 1/52; H01L 29/73

(52) U.S. Cl. CPC H01L 23/3735; H01L 29/73; H01L 29/66234; H03F 1/52
USPC 330/298; 257/565; 438/106

(57) ABSTRACT

Semiconductor devices are disclosed including a bulk substrate, an epitaxial collector layer, an epitaxial base layer, an epitaxial emitter layer and an electrical insulator layer in direct thermal contact with at least a portion of the base layer, emitter layer, and/or collector layer. At least a portion of the electrical insulator layer has high thermal conductivity properties, which can provide for dissipation of undesirable thermal energy through the electrical insulator layer.

### RELATED APPLICATION

This application claims the benefit of priority under 35 U.S.C. §119(e) of U.S. Provisional Application No. 61/805,405, filed on Mar. 26, 2013, and entitled “Semiconductor Device Heat Dissipation Using High Thermal Conductivity Dielectric Layer,” the disclosure of which is hereby incorporated by reference in its entirety.

### BACKGROUND

1. Field

The present disclosure generally relates to the field of electronics, and more particularly, to semiconductor devices.

2. Description of Related Art

Circuits and systems with active devices can generate heat that may need to be dissipated to some degree for proper device operation. Various techniques may be used for heat dissipation within semiconductor packages. However, physical dimensions/parameters and/or other considerations may make certain heat dissipation techniques undesirable or impractical in certain applications.

### SUMMARY

Certain embodiments disclosed herein provide a semiconductor die including a bulk substrate of a first impurity type having a top surface that lies in a top plane, an epitaxial collector layer of a second impurity type disposed adjacent to the top surface and lying in a plane parallel to the top plane, and an epitaxial base layer of the first impurity type disposed above the collector layer. The semiconductor die may further include an epitaxial emitter layer of the second impurity type disposed at least partially above the epitaxial base layer and an electrical insulator layer in direct thermal contact with at least a portion of one or more of the base layer, emitter layer, and collector layer, at least a portion of the electrical insulator layer having high thermal conductivity properties.

In certain embodiments, the semiconductor die electrical insulator layer includes Aluminum Nitride. The electrical insulator layer may have a thermal conductivity of greater than approximately 100 W·m−1·K−1. The electrical insulator layer can include a lower sublayer having low thermal conductivity and an upper sublayer having high thermal conductivity, the lower sublayer providing surface passivation for the at least a portion of one or more of the base layer, emitter layer and collector layer. In certain embodiments, the lower sublayer includes dielectric glass, and may have a thickness of less than approximately 0.1 μm, or approximately 500 Å or less. In certain embodiments, the lower sublayer has a thickness of approximately 100 Å or less.

The semiconductor die may include a metal layer disposed above the electrical insulator layer, such that thermal energy generated in the epitaxial collector layer may pass through at least a portion of the electrical insulator layer to the metal layer. In certain embodiments, the metal layer is not electrically active.

The semiconductor die may be configured to be disposed in a flip-chip package. In certain embodiments, the collector layer, base layer, and emitter layer are components of a bipolar transistor device. The bipolar transistor device may be a power amplifier device. For example, the bipolar transistor device may be a component of a central processing unit, or an oscillator device.

Certain embodiments disclosed herein provide a power amplifier module including a substrate for receiving a plurality of components. The module may include a controller component electrically connected to the substrate, a bipolar transistor power amplifier electrically connected to the substrate, and an electrical insulator layer in direct thermal contact with at least a portion of the bipolar transistor power amplifier, at least a portion of the electrical insulator layer having high thermal conductivity properties. The electrical insulator layer may include AlN.

Certain embodiments disclosed herein provide a process of manufacturing a semiconductor die. The process may include providing a bulk substrate of a first impurity type having a top surface that lies in a top plane, disposing an epitaxial collector layer of a second impurity type on the top surface, and disposing an epitaxial base layer of the first impurity type above at least a portion of the collector layer. The process may further include disposing an epitaxial emitter layer of the second impurity type above at least a portion of the base layer and disposing a passivation layer in direct thermal contact with at least a portion of one or more of the base layer, emitter layer, and collector layer, the passivation layer having high thermal conductivity and high electrical isolation properties. In certain embodiments, the process further includes packaging the semiconductor die in a flip-chip package.

Certain embodiments disclosed herein provide a semiconductor die including a bulk substrate of a first impurity type having a top surface that lies in a top plane, an active transistor device disposed or formed at least partially on the bulk substrate, and an electrical insulator layer in direct or indirect thermal communication with at least a portion of the active transistor device, at least a portion of the electrical insulator layer having high thermal conductivity properties. The active transistor device may be a FET transistor.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 illustrates a cross-sectional view of an embodiment of a transistor.

FIGS. 2A-2B illustrate perspective views of an embodiment of an electronic chip package having a heat sink associated therewith.

FIG. 3 illustrates a perspective view of an embodiment of an electronic chip in a flip-chip configuration.

FIG. 4 illustrates a cross-sectional view of an embodiment of a transistor having thermally conductive dielectric material associated therewith.

FIG. 5 illustrates a cross-sectional view of the transistor of FIG. 4 showing transfer of thermal energy therein.

FIG. 6 illustrates a top view of a transistor showing thermal energy transfer therein according to one embodiment.

FIG. 7 illustrates a cross-sectional view of an embodiment of a transistor having a metal strapping structure associated therewith.

FIG. 8 illustrates a perspective cross-sectional view of the transistor of FIG. 7 showing transfer of thermal energy therein according to one embodiment.

FIG. 9 illustrates an embodiment of a circuit board having an electronic module disposed thereon in accordance with one or more features of the present disclosure.

FIG. 10 is a block diagram showing an embodiment of a wireless device in accordance with one or more features of the present disclosure.

### DETAILED DESCRIPTION

Disclosed herein are example configurations and embodiments relating to transistor devices having relatively high thermal transfer characteristics. During operation, semiconductor devices may generate heat in one or more regions of the device. As excessive heat may be detrimental to device performance, heat dissipation may be a desirable or necessary function with respect to active semiconductor devices.

In certain embodiments, heat dissipation in semiconductor devices may be accomplished, for example, by attaching a semiconductor die onto a metal slug, or other heat sink structure. Other solutions may include integration of copper pillars in close proximity to heat-generating regions of the semiconductor, among possibly others. Heat transport through a semiconductor die to a metal slug can depend on a number of factors, including die thickness, semiconductor material, attachment methods, and/or other factors. While the use of metal slugs may be effective in removing some amount of thermal energy from semiconductor devices, die packaging dimensional constraints and/or physical layout or configuration may make the use of such metal slugs impractical or undesirable.

For example, chip-scale packaging solutions can include flip-chip mounting, wherein metal pillars or bumps on the surface of the semiconductor die are used to achieve electrical signal connectivity by flipping the finished semiconductor die onto pre-defined metal traces. In this context, heat dissipation may become problematic because the semiconductor die may not be attached to a metal slug. Rather, it may be necessary for heat to be primarily dissipated through surface metallization layers and/or terminating bumps. Such paths may be significantly more thermally resistive due to the relative thinness of the metal traces. Moreover, a dielectric material having poor thermal conductivity (e.g., boro-silicate glass) may be interposed between die metal layers, such that heat is primarily channeled along the metal traces to escape the die.

Issues associated with heat dissipation may make development of power amplifiers, and/or other devices, in a flip-chip, CSP form factor, or certain other configurations difficult. It may, therefore, be beneficial to incorporate dielectric materials into semiconductor devices that are not only good electrical insulators, but also have good thermal conductivity characteristics. In addition to issues associated with physical dimensions and configuration, cost considerations associated with heat-sink configurations may make such solutions undesirable. Therefore, a solution comprising relatively thermally-conductive dielectric material may provide a more cost-effective thermal management solution.

### Semiconductor Device Structure

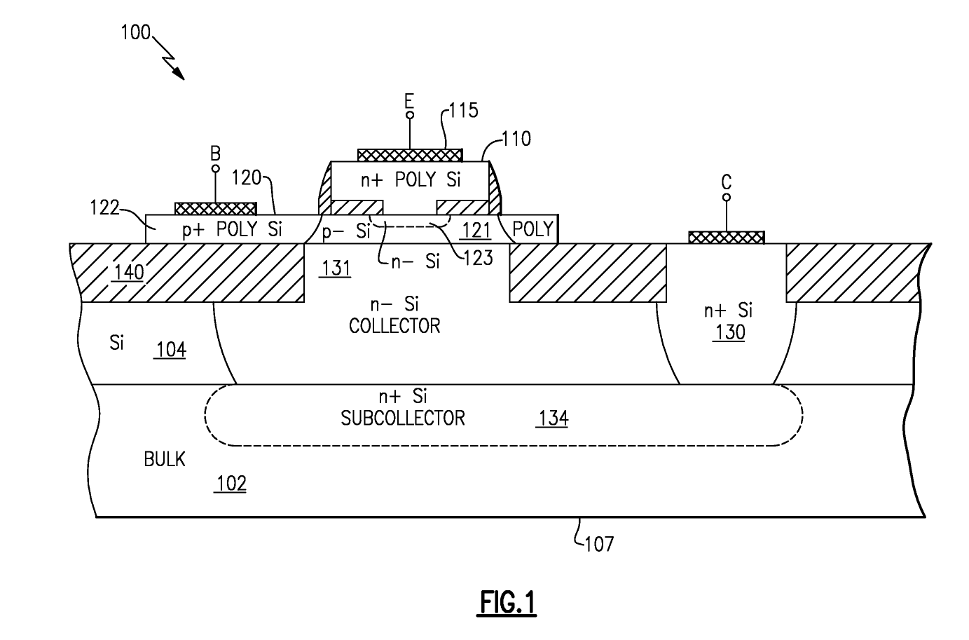

FIG. 1 illustrates a cross-section of an embodiment of a transistor device. While the illustrated device is an NPN bipolar transistor, principles described herein may be applicable to other transistor configurations, such as PNP bipolar transistors, or FET transistors. In certain embodiments, the device 100 includes a polysilicon emitter 110 with a metal contact 115 for transmission of electrical signals therefrom. The device 100 may be configured to operate at RF frequencies.

Devices like that shown in FIG. 1 may be fabricated using a bulk silicon substrate 102 with a layer of epitaxial silicon 104 grown thereon. The silicon layer 104 includes an extrinsic collector region 130, which is heavily doped with n-type impurities (or p-type for a PNP device). The device 100 further includes a lightly doped collector region 131, as well as a heavily doped sub-collector region 134. In certain embodiments, the silicon layer 104 is intrinsic outside of the illustrated collector regions. During operation of the device 100, heat may be generated, for example, in the collector region.

Portions of the silicon substrate may be etched away using a photolithographic process in order to allow for oxide growth 140 thereon. The oxide 140 may have high thermal and electrical isolation properties. The device 100 may include a p-type base region 120 above the collector region 131. As shown, the at least a portion of the base 120 may lie above an oxide layer. The portion of the base 120 that lies above the oxide layer may be primarily polysilicon deposit, whereas single-crystal silicon may be grown above the single-crystal collector region 131. The polysilicon region 122 is heavily doped, whereas the single-crystal region 121 may be generally intrinsic, or nearly undoped.

The n-type emitter (or p-type for PNP devices), as well as an additional oxide layer(s), may be formed above the base 120. In certain embodiments, the emitter is heavily doped. A depletion region 123 may form near the base-emitter junction and extend into the base layer due to the high concentration of impurities in the emitter. The semiconductor device 100 may further include a passivation layer (not shown) for passivating the semiconductor surface. For example, the passivation layer may advantageously serve as an electric insulator for preventing unwanted bleeding of signals propagating through the device, wherein metal traces and/or layers allow of signal passage therethrough. In certain embodiments, borosilicate glass, or other silicate glass, is used for passivation. Because of the high thermal resistivity generally associated with such materials, it may be necessary for heat exiting the top (as illustrated) of the device 100 to travel vertically and/or laterally primarily along thin metal contact wires/planes. The heat may exit the metal contacts and/or other portions of the device (e.g., an attached heat sink) into free space adjacent to the device. In certain embodiments, first level metals comprise copper or aluminum.

Heat dissipation in Semiconductor Devices

For certain applications, heat dissipation through the metal contact structures may not provide sufficient or desirable cooling for device operation. In certain embodiments, a semiconductor die includes multiple levels of metal, including interspaced oxide layers, through which heat may travel in order to exit the die. The various metal layers may be at least partially electrically isolated from one another and may provide connectivity to ground and/or other contacts. Certain embodiments disclosed herein provide dissipation of thermal energy through thermally-conductive passivation layers in addition to metal layers.

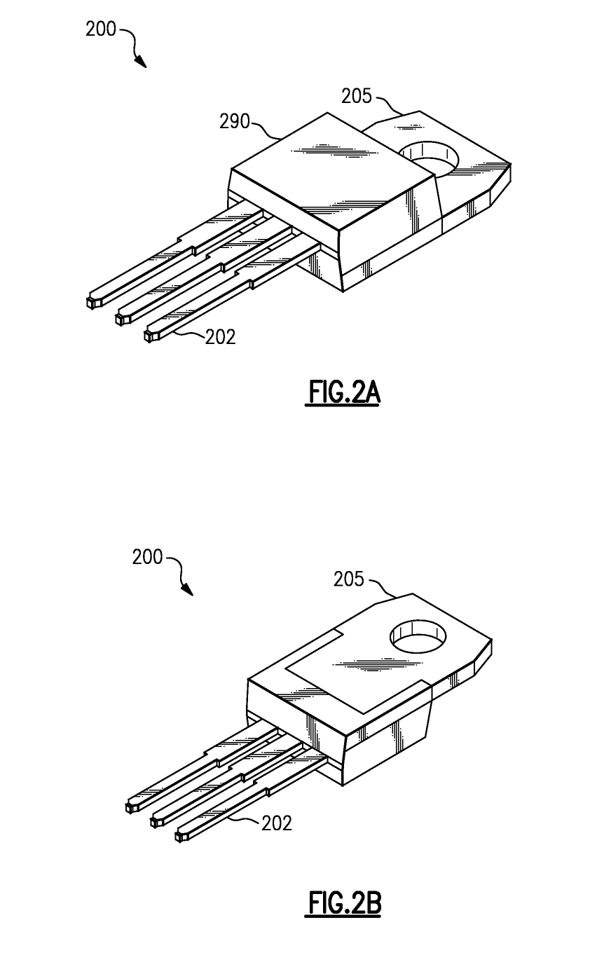

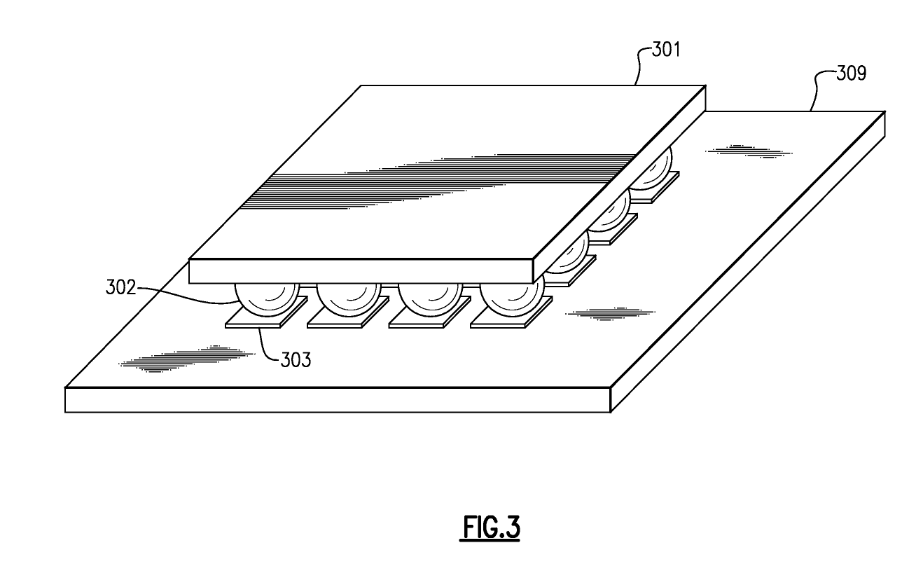

FIG. 2A illustrates a perspective top view of an embodiment of an electronic chip package having a heat sink associated therewith. The package includes an exterior housing 290, which may be made of plastic or other rigid material, for protecting internal circuitry and components from external influences. The package 200 may further include one or more metal pins 202 providing access for electrical contact to one or more internal components of the package. The package 200 further includes a heat sink structure 205 in direct or indirect thermal communication with an internal semiconductor die. Heat may be directed to the heat sink 205 where it can be dissipated in the surrounding environment. In certain embodiments, the package is exposed to fluid current, such as air, thereby providing convective heat transfer away from the heat sink. FIG. 2B illustrates a perspective bottom view of an embodiment of the electronic chip package shown in FIG. 2A.

In certain embodiments, heat travels through an internally-disposed semi-conductor, which might be approximately 100-500 μm thick. A back surface of the semiconductor die may be disposed in contact with the heat sink 205. In certain embodiments, the heat sink comprises material having high thermal conductivity and/or emissivity characteristics. For example, the heat sink 205 may comprise aluminum, copper, Beryllium-copper, or other material.

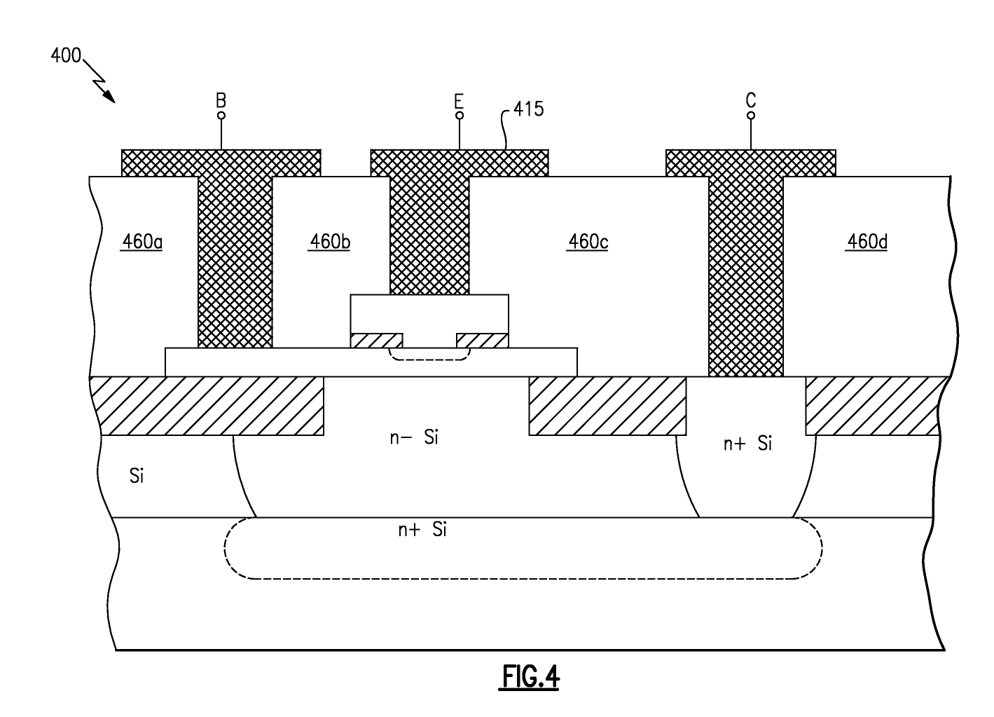

FIG. 3 illustrates a perspective view of an embodiment of an electronic chip 301 in a flip-chip mounting configuration. Whereas semi-conductor devices often comprise bond pads for connecting to bond wire, the chip 301 may terminate with metal bumps or pillars 302, which sit above the device. The metal balls 302 may be configured such that there is not substantial electrical contact between them. In certain embodiments, mounting the chip 301 may involve flipping the die over and attaching it to the circuit board 309, such that the bumps are aligned with, and contact, corresponding bond pads 303 on the circuit board 309. Once mounted, an epoxy or other substance may be injected underneath the die, such that it flows and solidifies around the bumps, thereby promoting adhesion of the die to the circuit board. In certain embodiments, the or height of a flip-chip may generally take into account merely the thickness of the die plus the thickness of the bumps or pillars, providing a total height of approximately 0.25-0.5 mm, or less. It may be impractical to utilize mounted heat sink techniques in flip-chip packages like that shown in FIG. 3.

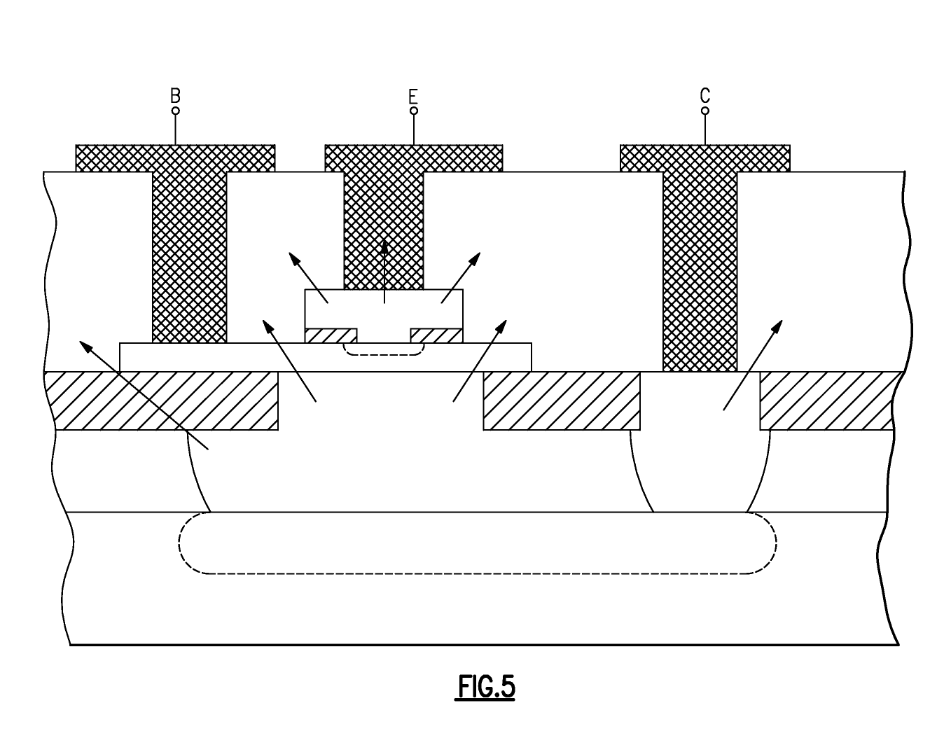

FIG. 4 illustrates a cross-sectional view of an embodiment of a transistor including semiconductor passivation portions 460. In embodiments in which the passivation portions 460 have high thermal resistivity, heat exiting through the top of the device may travel primarily along the metal contacts (e.g., emitter contact 415). Such metal traces may be thin and, therefore, the amount of heat that may be dissipated by travelling therethrough may be somewhat limited. As described above, the passivation portions 460 may comprise borophosphosilicate glass (BPSG) or other silicate glass deposition.

In certain embodiments, the first dielectric material 460 passivating the semiconductor die and in intimate contact with the semiconductor crystal regions comprises a material having relatively high thermal conductivity. For example, the layer 460 may include material having thermal conductivity greater than 100 W·m−1·K−1. In certain embodiments, the layer 460 comprises aluminum nitride (AlN), which may have thermal conductivity of approximately 140-180 W·m−1·K−1, while also exhibiting high electrical isolation properties (e.g., approximately 1×10-11 Ω−1·m−1). In certain embodiments, the layer 460 comprises beryllium oxide, which may have thermal conductivity of approximately 200-300 W·m−1·K−1, while also having high electrical isolation properties (e.g., approximately 1×10-12 Ω−1·m−1). Other diamond-like materials may also be suitable for heat dissipation in transistor devices according to one or more embodiments.

The dielectric layer 460 may be deposited or grown on the silicon substrate using any suitable technique. In certain embodiments, in addition to the thermally conductive oxide layer 460, the device 400 further includes one or more additional dielectric layers, such as between the thermally conductive dielectric 460 and the semiconductor surface. For example, the device 400 may include a very thin layer (e.g., between approximately 500 Å and 0.1 μm, or less than approximately 500 Å) of dielectric material, such as BPSG, BSG, PSG, or the like disposed between the thermally conductive layer 460 and the active device region(s). The thin layer(s) may be followed by AlN or other diamond-like material with high thermal conductivity, as described above. Use of a thin oxide layer may provide improved passivation properties. Furthermore, a thin layer may provide less of a thermal barrier than a comparable thicker layer of material.

FIG. 5 illustrates a cross-sectional view of the transistor of FIG. 4 showing transfer of thermal energy therein. The arrows shown in the figure are representative of possible thermal migration paths, wherein heat generated within the semiconductor device at least partially flows into one or more portions of thermally conductive dielectric material discussed above. For example, heat may be generated within an active collector region of the semiconductor device and at least partially flow to one or more portions of the thermally conductive dielectric material (e.g., AlN) through at least a portion of one or more of the following regions: shallow oxide trench at least partially contacting the collector region; base layer; emitter layer; emitter oxide; or metal traces.

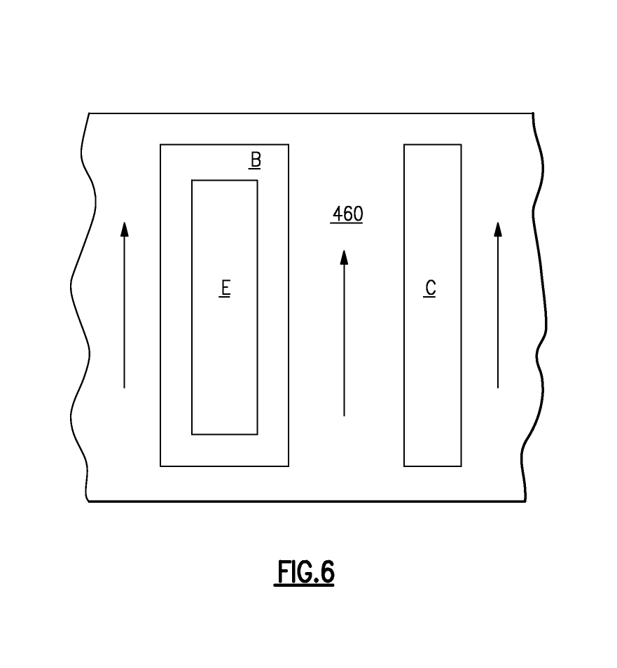

FIG. 6 illustrates a top view of a transistor showing thermal energy transfer therein according to one or more embodiments. While the view shown includes an emitter window (E), base portion (B), and collector bar portion (C), certain other regions or portions of the semiconductor device may be included that are not shown for illustrative convenience. For example, the device may include a base polysilicon portion that encompasses the emitter and the emitter window. As described above, thermal energy in the device may propagate to portions of the thermally conductive dielectric region 460.

In certain embodiments, thermal energy within the dielectric region 460 may propagate laterally, as indicated by the arrows in FIG. 6. An amount of thermal energy may travel laterally until it reaches an interface between the dielectric material and an adjacent material, such as air, at which point thermal energy may exit the semiconductor die. The flow of air or other fluid along the interface may increase thermal emission into the surrounding medium due to convective heat transfer.

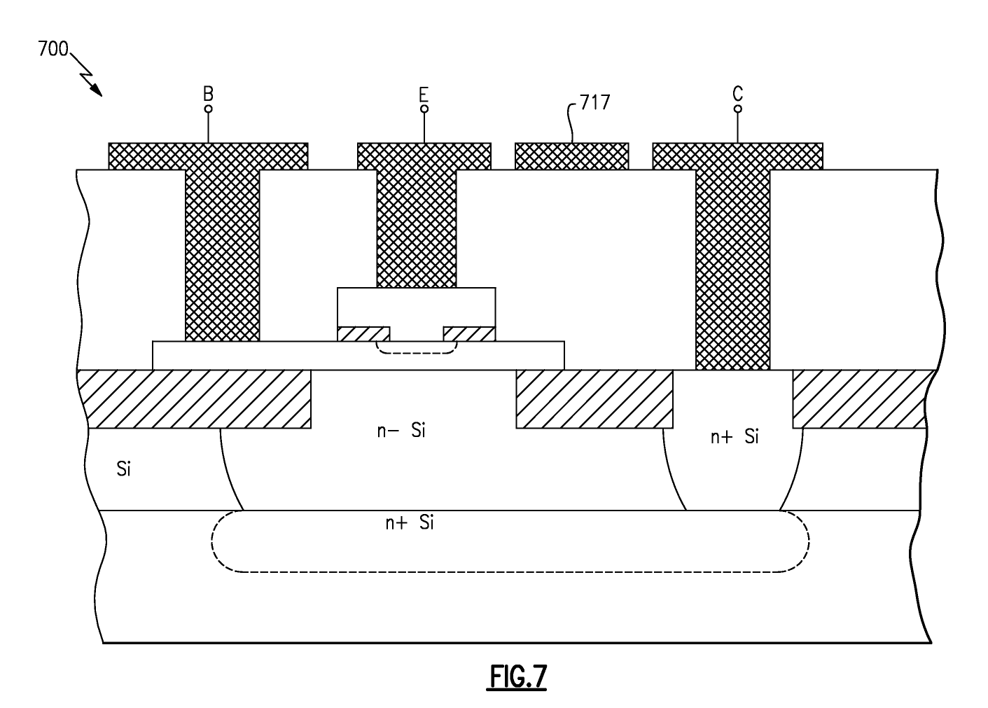

FIG. 7 illustrates a cross-sectional view of an embodiment of a transistor having a metal strapping associated therewith. Certain embodiments of semiconductor devices include a metal terminal (e.g., B, E, C) contacting the active device through the dielectric region (e.g., aluminum nitride), as shown. In addition, a metal or other thermally conductive channel 717 may be disposed in direct or indirect thermal communication with the active device. For example, the channel 717 may be disposed above an aluminum nitride dielectric layer, as shown, wherein the channel serves as a mechanism to dissipate heat away from the device 700.

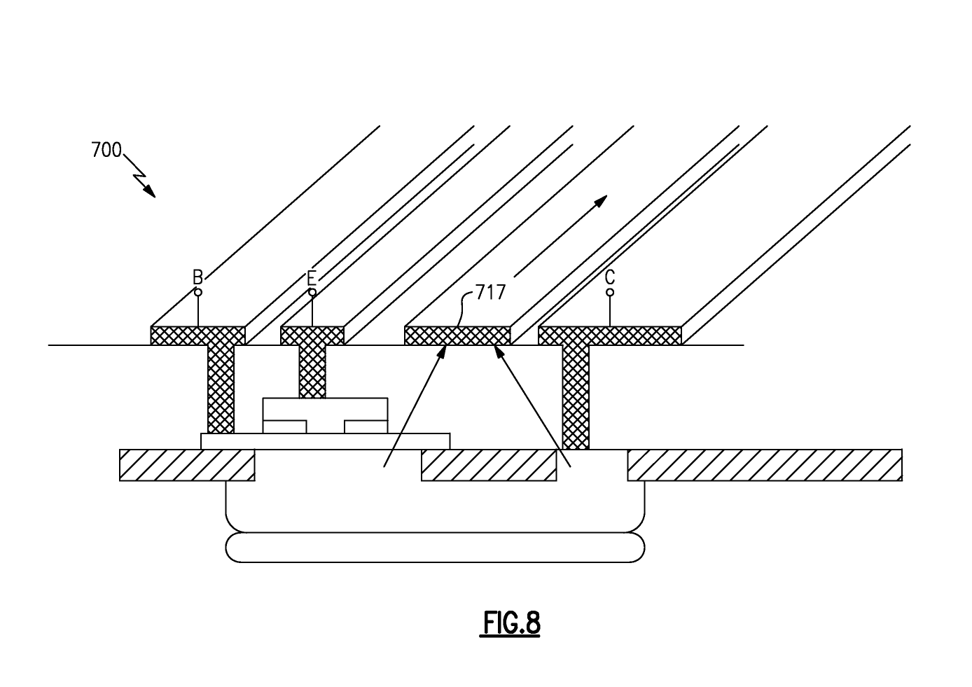

The channel 717 may comprise metal, such as aluminum, copper, or any other metal. In certain embodiments, the channel 717 comprises a type of metal that serves as a first level metal for the particular semiconductor technology. In certain embodiments, the channel 717 is not substantially electrically active. For example, the dielectric layer may serve to at least partially electrically isolate the channel 717 from electrically active regions. FIG. 8 illustrates a perspective cross-sectional view of the transistor of FIG. 7 showing transfer of thermal energy therein. As shown in the figure, the channel 717 may extend laterally with respect to the transistor device 700, such that thermal energy may be directed away, for example, in the direction illustrated by the arrows. In certain embodiments, the channel 717 is configured to carry thermal energy away from the device to a terminating member, such as a bump or the like.

### Wireless Device Integration

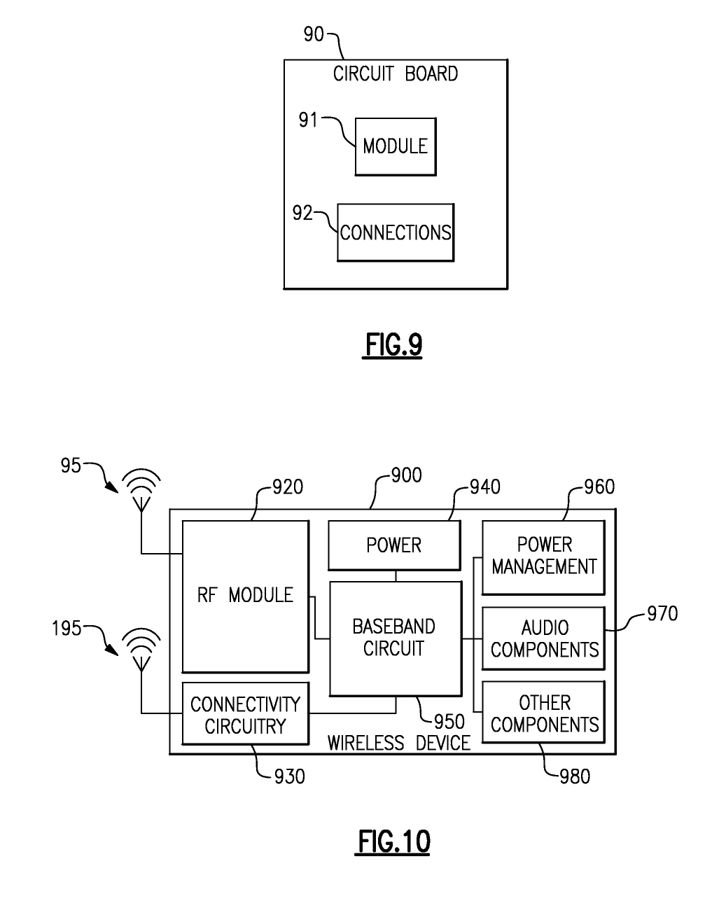

FIG. 9 illustrates an embodiment of a circuit board having an electronic module disposed thereon in accordance with one or more features of the present disclosure. The module 91 may include one or more devices comprising thermally conductive dielectric layers for heat dissipation, as described herein. For example, the module 91 may be an RF or other module including one or more active heat-generating transistor devices. In certain embodiments, certain features disclosed herein allow for the use of power amplifier and other devices in flip-chip configurations. Other potential modules may include CPU chips, or other chips that may rely to some extent on temperature stability to perform optimally. For example, temperature stability might affect the performance of a voltage controlled oscillator and/or switches, such as high power RF switches configured to transport a substantial amount of RF energy therethrough.

FIG. 10 illustrates an embodiment of a wireless device 900 in accordance with one or more aspects of the present disclosure. Applications of the present disclosure are not limited to wireless devices and can be applied to any type of electronic device including RF front-end circuitry. The application of thermally conductive device passivation layers in active devices associated with one or more components of the wireless device 900 may provide improved heat dissipation in certain embodiments. The wireless device 900 can include an RF module 920. In certain embodiments, the RF module 920 includes multiple signal-processing components. For example, the RF module 920 may include discrete components for amplification and/or filtering of signals in compliance with one or more wireless data transmission standards, such as GSM, WCDMA, LTE, EDGE, WiFi, etc.

The RF module 920 may include transceiver circuitry. In certain embodiments, the RF module 920 comprises a plurality of transceiver circuits, such as to accommodate operation with respect to signals conforming to one or more different wireless data communication standards. Transceiver circuitry may serve as a signal source that determines or sets a mode of operation of one or more components of the RF module 920. Alternatively, or in addition, a baseband circuit 950, or one or more other components that are capable of providing one or more signals to the RF module 920 may serve as a signal source provided to the RF module 920. In certain embodiments, the RF module 920 can include a digital to analog convertor (DAC), a user interface processor, and/or an analog to digital convertor (ADC), among possibly other things.

The RF module 920 is electrically coupled to the baseband circuit 950, which processes radio functions associated with signals received and/or transmitted by one or more antennas (e.g., 95, 195). Such functions may include, for example, signal modulation, encoding, radio frequency shifting, or other function. The baseband circuit 950 may operate in conjunction with a real-time operating system in order to accommodate timing dependant functionality. In certain embodiments, the baseband circuit 950 includes, or is connected to, a central processor. For example, the baseband circuit 950 and central processor may be combined (e.g., part of a single integrated circuit), or may be separate modules or devices.

The baseband circuit 950 is connected, either directly or indirectly, to a memory module 940, which contains one or more volatile and/or non-volatile memory/data storage, devices or media. Examples of types of storage devices that may be included in the memory module 940 include Flash memory, such as NAND Flash, DDR SDRAM, Mobile DDR SRAM, or any other suitable type of memory, including magnetic media, such as a hard disk drive. Furthermore, the amount of storage included in memory module 940 may vary based on one or more conditions, factors, or design preferences. For example, memory module 940 may contain approximately 256 MB, or any other suitable amount, such as 1 GB or more. The amount of memory included in the wireless device 900 may depend on factors such as, for example, cost, physical space allocation, processing speed, etc.

The wireless device 900 includes a power management module 960. The power management module 960 includes, among possibly other things, a battery or other power source. For example, the power management module 960 may include one or more lithium-ion batteries. In addition, the power management module 960 may include a controller module for management of power flow from the power source to one or more regions of the wireless device 900. Although the power management module 960 may be described herein as including a power source in addition to a power management controller, the terms “power source” and “power management,” as used herein, may refer to either power provision, power management, or both, or any other power-related device or functionality.

The wireless device 900 may include one or more audio components 970. Example components may include one or more speakers, earpieces, headset jacks, and/or other audio components. Furthermore, the audio component module 970 may include audio compression and/or decompression circuitry (i.e., “codec”). An audio codec may be included for encoding signals for transmission, storage or encryption, or for decoding for playback or editing, among possibly other things.

The wireless device 900 includes connectivity circuitry 930 comprising one or more devices for use in receipt and/or processing of data from one or more outside sources. To such end, the connectivity circuitry 930 may be connected to one or more antennas 195. For example, connectivity circuitry 930 may include one or more power amplifier devices, each of which is connected to an antenna. The antenna 195 may be used for data communication in compliance with one or more communication protocols, such as WiFi (i.e., compliant with one or more of the IEEE 802.99 family of standards) or Bluetooth, for example. Multiple antennas and/or power amplifiers may be desirable to accommodate transmission/reception of signals compliant with different wireless communications protocols. Among possibly other things, the connectivity circuitry 930 may include a Global Positioning System (GPS) receiver.

The connectivity circuitry 930 may include one or more other communication portals or devices. For example, the wireless device 900 may include physical slots, or ports, for engaging with Universal Serial Bus (USB), Mini USB, Micro USB, Secure Digital (SD), miniSD, microSD, subscriber identification module (SIM), or other types of devices through a data-communication channel.

The wireless device 900 includes one or more additional components 980. Examples of such components may include a display, such as an LCD display. The display may be a touchscreen display. Furthermore, the wireless device 900 may include a display controller, which may be separate from, or integrated with, the baseband circuit 950 and/or a separate central processor. Other example components that may be included in the wireless device 900 may include one or more cameras (e.g., cameras having 2 MP, 3.2, MP, 5 MP, 10 MP, or other resolution), compasses, accelerometers, or other functional devices.

The components described above in connection with FIG. 10 and wireless device 900 are provided as examples, and are non-limiting. Moreover, the various illustrated components may be combined into fewer components, or separated into additional components. For example, the baseband circuit 950 can be at least partially combined with the RF module 920. As another example, the RF module 920 can be split into separate receiver and transmitter portions.

While various embodiments of integrated front-end modules have been described, it will be apparent to those of ordinary skill in the art that many more embodiments and implementations are possible. For example, embodiments of integrated FEMs are applicable to different types of wireless communication devices, incorporating various FEM components. In addition, embodiments of integrated FEMs are applicable to systems where compact, high-performance design is desired. Some of the embodiments described herein can be utilized in connection with wireless devices such as mobile phones. However, one or more features described herein can be used for any other systems or apparatus that utilize of RF signals.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A semiconductor die comprising:
a bulk substrate of a first impurity type having a top surface that lies in a top plane;
an epitaxial collector layer of a second impurity type disposed adjacent to said top surface and lying in a plane parallel to said top plane;
an epitaxial base layer of said first impurity type disposed above said collector layer;
an epitaxial emitter layer of said second impurity type disposed at least partially above said epitaxial base layer; and
an electrical insulator layer in direct thermal contact with at least a portion of one or more of said base layer, emitter layer, and collector layer, at least a portion of said electrical insulator layer having high thermal conductivity properties.

2. The semiconductor die of claim 1 wherein said electrical insulator layer comprises Aluminum Nitride.

3. The semiconductor die of claim 1 wherein said electrical insulator layer has a thermal conductivity of greater than approximately 100 W·m⁻¹·K⁻¹.

4. The semiconductor die of claim 1 wherein said electrical insulator layer comprises a lower sublayer having low thermal conductivity and an upper sublayer having high thermal conductivity, said lower sublayer providing surface passivation for said at least a portion of one or more of the base layer, emitter layer and collector layer.

5. The semiconductor die of claim 4 wherein said lower sublayer comprises dielectric glass.

6. The semiconductor die of claim 4 wherein said lower sublayer has a thickness of less than approximately 0.1 μm.

7. The semiconductor die of claim 4 wherein said lower sublayer has a thickness of approximately 500 Å or less.

8. The semiconductor die of claim 4 wherein said lower sublayer has a thickness of approximately 100 Å or less.

9. The semiconductor die of claim 1 further comprising a metal layer disposed above said electrical insulator layer, such that thermal energy generated in the epitaxial collector layer may pass through at least a portion of said electrical insulator layer to said metal layer.

10. The semiconductor die of claim 9 wherein said metal layer is not electrically active.

11. The semiconductor die of claim 1 wherein said die is configured to be disposed in a flip-chip package.

12. The semiconductor die of claim 1 wherein said collector layer, base layer, and emitter layer are components of a bipolar transistor device.

13. The semiconductor die of claim 12 wherein said bipolar transistor device is a power amplifier device.

14. The semiconductor die of claim 12 wherein said bipolar transistor device is a component of an oscillator device.

15. A power amplifier module comprising:
a substrate for receiving a plurality of components;
a controller component electrically connected to the substrate;
a bipolar transistor power amplifier electrically connected to the substrate; and
an electrical insulator layer in direct thermal contact with at least a portion of said bipolar transistor power amplifier, at least a portion of said electrical insulator layer having high thermal conductivity properties.

16. The power amplifier module of claim 15 wherein the electrical insulator layer comprises AlN.

17. A method of manufacturing a semiconductor die comprising:
providing a bulk substrate of a first impurity type having a top surface that lies in a top plane;
disposing an epitaxial collector layer of a second impurity type on the top surface;
disposing an epitaxial base layer of the first impurity type above at least a portion of the collector layer;
disposing an epitaxial emitter layer of the second impurity type above at least a portion of the base layer; and
disposing a passivation layer in direct thermal contact with at least a portion of one or more of the base layer, emitter layer, and collector layer, said passivation layer having high thermal conductivity and high electrical isolation properties.

18. The method of claim 17 further comprising packaging the semiconductor die in a flip-chip package.

19. (canceled)

20. (canceled)
